(19) United States
(12) Patent Application Publication
(10) Pub. No.: US 2004/0112858 A1
(43) Pub. Date: Jun. 17, 2004

(54) Method for dispersing spacer on the substrate of a liquid crystal display element and apparatus for dispersion therewith

(76) Inventor: Michael W. Yang, Marietta, GA (US)

Correspondence Address: Michael W. Yang, 1085 Arden Dr., Marietta, GA, 30008, US

(21) Appl. No.: 10/689,683

(22) Filed: Oct. 22, 2003

Related U.S. Application Data
(63) Continuation of application No. 10/310,634, filed on Dec. 6, 2002.
(60) Provisional application No. 60/388,690, filed on Jun. 14, 2002.

(51) Int. Cl. C30B 33/00

(52) U.S. Cl. 216/23

(57) ABSTRACT

The present invention is directed to a method for placing spacer uniformly and securely onto the substrate of a liquid crystal display element, comprising the steps of: (a) Preparing an UV [or thermal] curable resin containing spacer particles. (b) Dispersing certain amount of above spacer-resin mixture on a gravure cylinder with well finished designed cells to be used as the spacer-resin carrier. (c) Removing excess spacer-resin mixture and forced on spacer particle with resin into each hole by means of doctor knife. (d) Transferring individual spacer-resin onto a second smooth surfaced roller according to the designed pattern by means of contact. (e) Transferring individual patterned spacer-resin onto the surface of substrate of a liquid crystal display element from the second roller with any conventional coating methods. Likewise, the edge sealant for LCD can be placed by a similar method.

### CROSS REFERENCE TO RELATED APPLICATION

This application claims priority to U.S. Provisional Application Serial No. 60/388690 filed on Jun. 14, 2002 and is a Continuation-in-part of U.S. application Ser. No. 10/310634 filed on Dec. 6, 2002, which are all herein incorporated by reference in their entireties.

### STATEMENT REGARDING FEDERALLY SPONSORED RESEARCH OR DEVELOPMENT

Not Applicable.

### BACKGROUND OF THE INVENTION

The present invention relates to a method for dispersing spacer particles on the substrate of a liquid crystal display element in the process for producing the flat panel display device and relates to apparatus using for this dispersing method.

A liquid crystal display (LCD) is composed of two opposed electrode substrates and spacers and liquid crystal materials wherein the spacers and liquid crystal materials are interposed between the electrode substrates. A typical liquid crystal display has a structure as shown in FIG. 1. The spacers have used for the purpose of keeping liquid crystal at a uniform and constant thickness.

Generally, high speed of response, high contrast, a wide viewing angle, etc. are among display performance characteristics as such as demand in practical use of the liquid crystal display. For these performance characteristics to be realized, the thickness of the liquid crystal layer, namely, the gap distance between the two electrode substrates must be kept strictly constant. Conventionally, the dispersion of the spacer particles falls into two processes as shown in FIGS. 2A and 2B.

In wet process (FIG. 2A), spacer particles are mixed into a solvent such as fluorocarbon, alcohol, or a water-alcohol mixed solvent and sprayed the liquid onto the substrate. However, the wet process has following problems; regulation against fluorocarbon; environmental contamination and flaming due to organic solvents; and damage or contamination to an oriented polyimide layer due to the solvents.

In dry process (FIG. 2B) spacer particles are directly sprayed onto the substrate with a compressed gas such as nitrogen. However, particles aggregate during dispersion, and this results in an uneven distribution of spacers on the substrate. Therefore, it is difficult to keep the gap distance between electrode substrates constant, resulting low quality and low yield of the liquid crystal panel.

Since in these applications, the spacer particles are not anchored to the substrate, the spacers may shift or migrate to cause artifacts to appear in those areas in the display cell. The spray application presents an additional issue in the manufacturing process. The display panel is assembled in class 10 to 100 clean rooms to meet the optical quality requirements for the liquid crystal displays. Spraying particles on to a surface of substrate results in many of the particles become airborne, thus making it difficult to maintain class 10 to 100 standards.

One attempt to overcome some of the deficiencies as described above is disclosed in U.S. Pat. No. 4,983,429. Where the spacer containing adhesive was coated on substrate by means of letterpress printing in a dot-like or stripe-like pattern in order to producing a cell with a mean diameter of 1 to 4 um. However, a dot in letterpress printing has a diameter of 60 um or less, thus means each dot contains a cluster of spacers, which usually has a diameter of 1 um to 10 um (see FIG. 2(b) of U.S. Pat. No. 4,983,429). In the presence of those clusters, would result starved area in the display panel where the cell was filled with liquid crystal materials.

In order to distributing spacer particles uniformly on LCD element substance, Matoba, et al (U.S. Pat. No. 5,838,413) proposed a method to supply and allocate spacer particles onto a particle distributing jig plate having numerous spacer particle positioning depressed positions for receiving the spacer particles in a one to one correspondence, then the particles distributing jig plate is made to face, and be registered with, the liquid crystal display element substrate, so that the spacer particles allocated to the depressed portions are transferred to the substrate of a liquid crystal display element. However, during the operation, spacer particle supplying device delivers spacer particles of greater number than depressed portions formed on the top surface of particle distributing jig plate, the excess spacer particles were then shaken-off from jig plate by tilting the plate at certain angle with vibration. Thus a large amount of valuable spacer particles are wasted. Furthermore, the design proposed by Matoba et al involves distributing dry spacer onto a substrate, resulting in deficiencies similar to those of conventional spray method that spacer may move or migrate during filling of liquid crystal materials.

Therefore, there is clearly a need for a method to accurate placement of structurally support spacers that are cost effect, reliable and eliminate interference with the optical integrity of the display panel.

### BRIEF SUMMARY OF THE INVENTION

It is, therefore, an object of the invention to provide a method for dispersing spacer particles on the substrate of a liquid crystal display element uniformly and securely.

In accordance with a first aspect of the present invention, there is provided a method for placing spacer uniformly and securely onto the substrate of a liquid crystal display element, comprising the steps of:

(A) Preparing an UV (or thermal) curable resin containing spacer particles.

(B) Dispersing certain amount of above spacer-resin mixture on a gravure cylinder with well-finished designed pattern holes to be used as the spacer-resin carrier. The opening diameter and the depth of the hole on the gravure cylinder is around 105%-195% of the diameter of spacer particle.

(C) The doctor blade will force only one spacer with resin into the each hole on the gravure cylinder and remove the excess spacer-resin away from the surface of gravure cylinder.

(D) When gravure cylinder in contact with the second cylinder, the individual spacer with resin will transfer to the surface of second cylinder according to the design pattern.

(E). These individual spacers (with resin) can then be transferred faithfully onto the surface of LCD substrate by any conventional printing method. For the convenience of process, these spacers with resin should be transferred to the substrate which would be used as the lower layer of LCD panel.

In according with a second aspect of the present invention, there is provide a method for placing the edge sealant on the substrate of a LCD element, comprising the steps of:

(A) Preparing an UV (or thermal) curable resin containing spacer particles.

(B) Dispersing certain amount of above spacer-sealant mixture on a gravure cylinder with a channel-like designed pattern for seal to be used as the spacer-sealant carrier.

(C) Removing excess spacer-sealant mixture by doctor blade and forced the correct amount spacer-sealant mixture into the channel. The depth of the channel is around 105-195% of the diameter of the spacer particle, more importantly, the depth of channel should be the same as the depth of hole.

(D) When gravure cylinder in contact with the second cylinder, the strip of spacer-sealant mixture will transfer to the surface of second cylinder according to the design pattern.

(E) The strip can then be transferred faithfully onto the surface of LCD substrate by any conventional printing method. For the convenience of process the strip with sealant-sealant mixture should be transferred to the substrate which would be used as the upper layer of LCD panel.

In accordance with a third aspect of the present invention, the resin used in the above features is composing of:

(A) UV or thermal curable polyurethane (methyl) acrylate oligomers, acrylated epoxy oligomers or/and acrylated polyester oligomers.

(B) Vinyl monomers, (methyl) acrylate monomers.

(C) Photo or thermal initiators.

(D) Additives; such as dispersants, surfactants, antioxidants, light stabilizers and coating aids which aiding dispersing ability of spacer particles during mixing or impart other desirable properties to the spacer-resin mixture as known to those skilled in the art.

In accordance with a fourth aspect of the invention, the gravure roller used as carrier for spacer-resin should coated with hydrophobic non-adhesive low surface energy layer, such as Teflon coating so that spacer-resin on the surface can be fully removed by doctor blade. The retained spacer-resin in the holes can also be easily transferred to the second smooth cylinder.

In accordance with a fifth aspect of the invention, the gravure roller used as carrier for space-resin as described at first feature should be graving with many individual cells and the open diameter and the depth of the hole is around 105-195% of the diameter of the spacer particle so that only allow one spacer with resin to fill each hole.

In accordance with a sixth aspect of the invention, the gravure roller used as carrier for spacer-sealant compound as described at second feature should have a channel-like design pattern. The width of the channel would meet the requirement for ordinary seal, however, the depth of channel should be around 105-195% of the diameter of the spacer particle. More important, the depth of the channel should be same as the depth of the hole, so that when two opposing substrates are bonded to form the LCD panel has an even spacing.

In accordance with a seventh aspect of the invention, the gravure roller described either in fifth feature or sixth feature can be engraved the metal cylinder first, then coated with a thin layer of hydrophobic, non-adhesive coating, such as low surface energy polymeric films described in Macromolecules p.6920-6929 (2002).

In accordance with an eighth aspect of the invention, the sealant compound used in the second feature is composing of:

(A) UV or thermal curable polyurethane (methyl) acrylate oligomers, and/or acrylated polyester oligomers.

(B) Vinyl monomers, (methyl) acrylate monomers.

(C) An epoxy acrylates.

(D) Photo or thermal initiators.

(E) Additives; such as dispersants, surfactants, antioxidants, light stabilizers and coating aids which may be included to aide dispersing ability of spacer particles during mixing or impart other desirable properties to the spacer-sealant mixture as known to those skilled in the art.

In accordance with a ninth aspect of the invention, two coated substrates can than be bonded together through the sealant compound by means of UV radiation curing or heat treatment curing. The spacers were also immobilized on the substrates after curing.

### BRIEF DESCRIPTION OF THE FIGURES OF THE DRAWINGS

The above and other objects and features of the present invention will become apparent from the following description of preferred embodiments given in connection with the accompanying drawings, wherein:

FIG. 1 is a diagrammatic view of liquid crystal display panel.

FIGS. 2A and 2B are illustration of two processes for dispersing spacer particles on the substrate.

FIG. 3 is a plane view of gravure cylinder with designed pattern holes as spacer-resin carrier.

FIG. 4 is a section view of designed pattern holes on gravure cylinder.

FIG. 5 is a diagrammatic view of dispensing system according to the present invention.

FIG. 6A is a front view of gravure cylinder with channel design used as spacer-sealant carrier.

FIG. 6B is the back view of same engraved gravure cylinder with channel design used as spacer-sealant carrier.

FIG. 6C is a plane view with several small channel design engraved on one gravure cylinder used as spacer-sealant carrier.

FIG. 7 is a section view of channel design on gravure cylinder using as spacer-sealant carrier.

### DETAILED DESCRIPTION OF THE INVENTION

The present invention may be understood more readily by reference to the following detailed description of preferred embodiments of the invention.

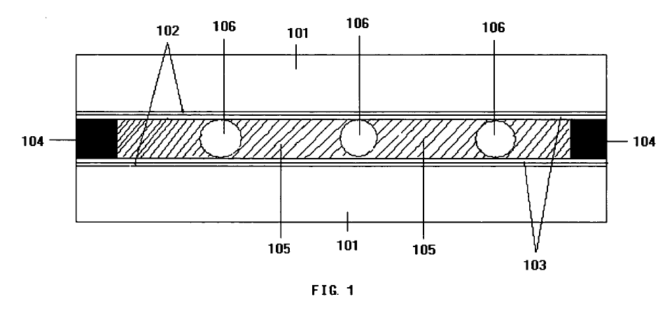

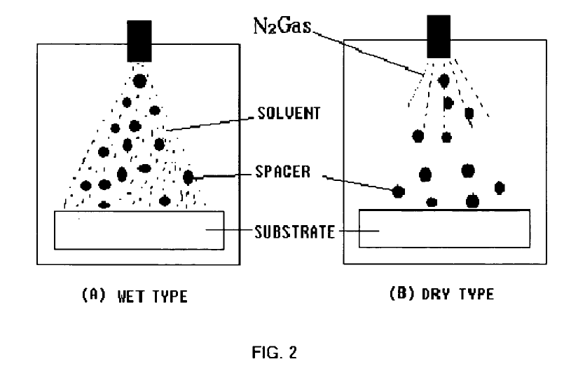

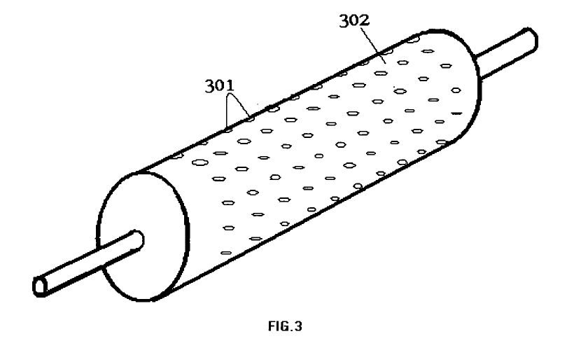

A liquid crystal display has a structure shown in FIG. 1. Specially, a transparent electrode 102 and an orientation film 103 are placed on the surface of each of upper and lower glass plate 101. The peripheral portions of glass substrate (101+102+103) are sealed with a sealing compound 104 and liquid crystal material 105. In order to maintain the liquid crystal cell gap constant, spacers 106 for the liquid crystal are disposed in an evenly distributed manner.

The cell spacing can be determined by the type of spacers are used. That is, when spherical spacers are used, the cell spacing is determined by a diameter of sphere and when rod-like spacers are used, the cross section diameter of the spacers determines the cell spacing.

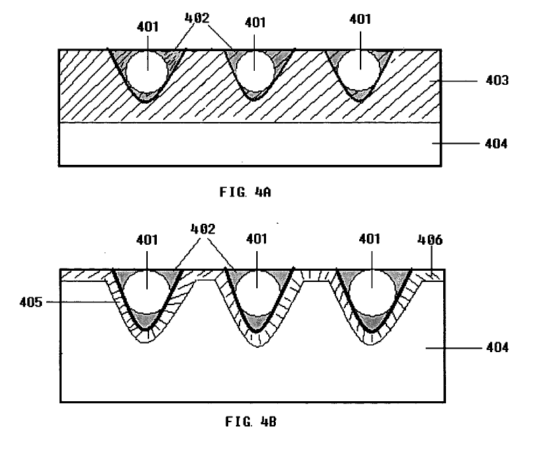

FIGS. 3 and 4 show the plane and the section views of the gravure cylinder, engraved with well design-patterned holes, used as a spacer-resin carrier. As shown in FIG. 4A, a metal gravure cylinder 404 was fitted with a Teflon sleeve 403 (or use a one piece Teflon gravure cylinder), which was engraved with well patterned holes 405 to be filled with spacer-particle 401 and the curable resin 402. The opening diameter and the depth of each hole is around 105-195% of the diameter of the spacer particle, so each hole will only be filled with one spacer particle with resin during operation. Alternatively, as shown in FIG. 4B, the metal gravure cylinder 404 can be engraved with well patterned holes 405 and then coated a thin layer of Teflon-like coating 406. The Teflon-like coating can either be Teflon or low surface energy fluorinated polymer films described in Macromolecules p.6920-6929 (2002).

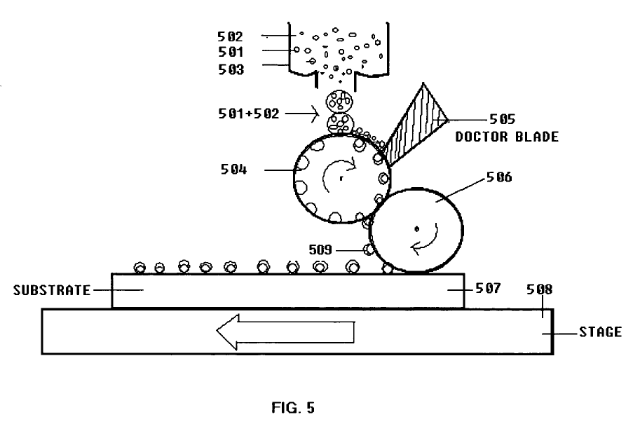

FIG. 5 is a diagrammatic view to illustrate the dispersing method for spacer particles in accordance with the present invention. The spacer particles 501 are premixed well with an UV (or thermal) curable resin mixture 502 in a container 503, then controlled amount of spacer-resin mixture (501+502) is dispersed on a gravure cylinder 504 which has designed holes as described in FIGS. 3 and 4. The cylinder is rolling at the direction of pointed arrow as indicated in the FIG. 5. A stationary doctor blade 505 is closely in contact with the surface of the gravure cylinder 504. When the spacer-resin mixture (501+502) reached the spot with the doctor blade 505, only one spacer particle with resin will be forced into each hole on gravure cylinder and the excess portion will be removed by the function of the doctor blade. then each spacer-resin drop 509 can be transferred from the gravure cylinder 504 onto the second roller cylinder 506,which has a smooth surface and moving at the direction of arrow as indicated in the FIG. 5, according to the designed pattern. By placing the substrate 507 (as 101+102+103 in FIG. 1) on a moving stage 508 with setup and moving direction as indicated in the FIG. 5, each spacer-resin drop 509 can now be faithfully transferred on to the surface of substrate 507.

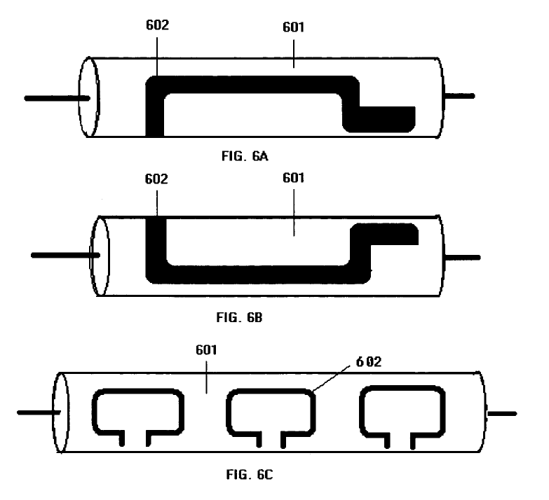

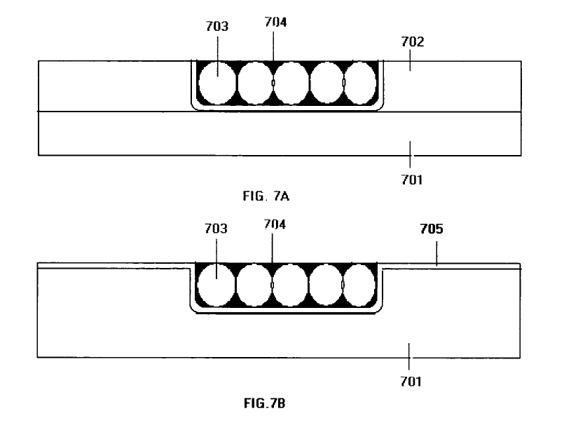

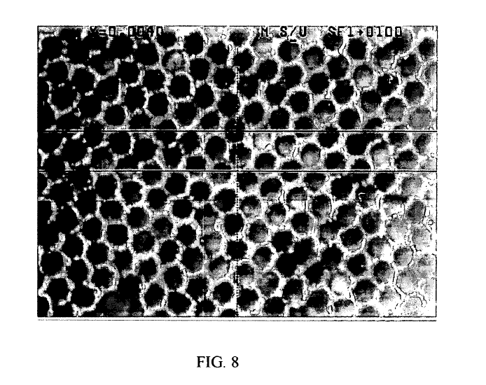

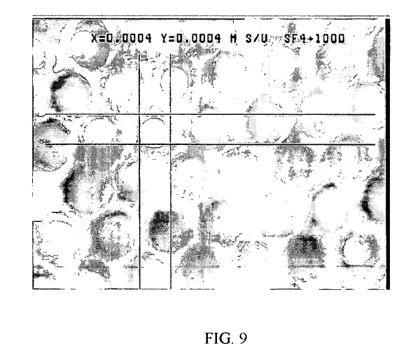

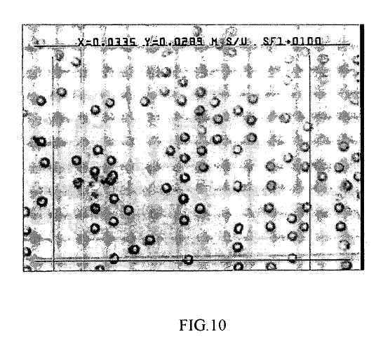

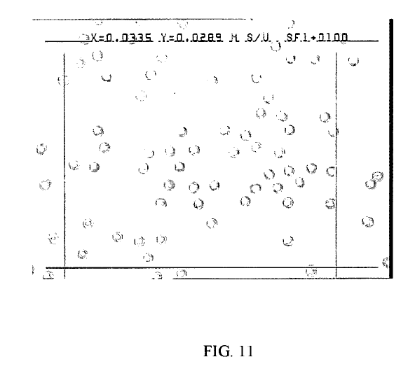

FIGS. 6A and 6B show a front and back views of an engraved gravure cylinder with a channel 602 designed if only one sealant pattern can be fitted into one gravure cylinder 601. FIG. 6C shows of more than one sealant patterns can be fitted into one gravure cylinder, which is now used as a spacer-sealant carrier. As indicated in FIG. 4A, the designed channel pattern can be similarly engraved on a hydrophobic, non-adhesive Teflon sleeve 702 which is covered on a metal gravure cylinder 701 as shown in FIG. 7A. Alternatively, the channel pattern can be engraved on the metal gravure cylinder 701, then coated with a thin layer of Teflon-like material 705 as shown in FIG. 7B. The width of the designed channel will be fitted to the regular sealant width according to the specifications, which is well known in the art, however, the depth of the channel should be the same as the depth of the hole for spacer as described in FIGS. 4A and 4B. The channel should be able to fill a group of spacer particles with the sealant compounds. The method of dispersing spacer 703-sealant 704 is similar to the method as described in FIG. 5, except replacing patterned gravure cylinder 504 with a patterned gravure cylinder as described in FIGS. 6A, 6B and 6C.

In an other embodiment of the present invention, the resin mixture used for spacer-resin dispersions comprising of: (a) UV or thermal curable polyurethane (meth)acrylate oligomers, acrylated epoxy oligomers, and/or acrylated polyester oligomers. (b) radical polymerizable monomers, (c) photo-initiators or thermal-initiators and (d) additives.

Polyurethanes are a general class of polymer that contain at least two —NHCOO— linkages in the backbone of the polymer, optionally along with other functional groups in the backbone such as esters, ethers, urea and amides. Polymers prepared from urethane oligomers exhibit good abrasion resistance, toughness, flexibility, clarity, and stain resistance. These properties have made urethanes useful in the coatings industry.

There are a wide variety of ways known to those skilled in the art to prepare urethane polymers. Urethane prepolymers are typically reaction products of aliphatic or aromatic polyols, polyesters, or polyethers of diverse composition with a stoichiometric excess of diisocyanate. Typically, the number of terminal hydroxyl groups of the polyol, polyester, or polyether is two or greater. The terminal hydroxyl groups react with the diisocyanate to produce urethane linkages, and the resulting prepolymer becomes end capped with isocyanate groups. Depending on the stoichiometric ratio of NCO/OH groups, the urethane linkage can also be incorporated into the backbone of the isocyanate terminated oligomer. Different urethanes can be obtained by changing (1) the diusocyanate, (2) the polyol, polyester, or polyether, or (3) the NCO/OH stoichiometric ratio. For a description or urethane oligomers and polymers, see Frisch, K. C., Applied Polymer Science eds. J. K. Craver and R. W. Tess), chapter 54, p.828, ACS, ORPL, Washington, 1975.

Urethane prepolymers are made radiation curable by adding acrylate or methacrylate groups to the prepolymer. This is typically accomplished by reaction the isocyanate terminated oligomer with hydroxy substituted acrylates or methacrylates. Alternatively, acrylate or methacrylate esters that include other functional groups that can react with an isocyanate can also be used, such as epoxy containing compounds as glycidyl acrylate or methacrylate, or amino containing esters such as aminoalkyl or aminoaryl acrylate or methacrylate.

Urethane (meth)acrylates containing between two and six acrylate or methacrylate functional groups are readily available in industry. Examples of suitable commercial acrylate or methacrylate terminated urethanes that can be used in the polymerizable composition disclosed herein include but are not limited to urethane acrylates 230, 270, 4827, 6700, 8402 and 8804 from UCB Radcure, urethane acrylates CN953, CN962, CN964, CN965, CN980 and CN981 from Sartomer Company.

In order to facilitate total transferring the spacer-resin mixture from a highly hydrophobic, low surface tension fluoropolymer coated gravure roller onto the second smooth roller, the resin mixture should have high surface tension and with a flowable viscosity. Since urethane (meth)acrylates are usually highly viscose, therefore a low viscose monomer with high surface tension should be used as a diluent to improve the process ability of the final resin and to impart the desirable properties.

Examples of such radical-polymerizable monomer included generally a vinylic monomer, an allylic monomer, an acrylic monomer and a methacrylic monomer, in which acrylic monomer and a methacrylic monomer are preferred. The prefer viscosity of (meth)acrylic monomer is below 100 cps at 25° C. and with the surface tension of higher than 38 dynes/cm at 20° C.

The monomers can be mono-functional, di-functional, or multi-functional, wherein the term “functional” is used to refer to groups that are reactive on curing with radiation, such as acrylate and methacrylate.

The monomer should be chemically compatible with the acrylate or methacrylate oligomers used in the polymerizable composition. The monomer is considered compatible if phase separation does not occur on polymerization of the composition.

Examples of suitable commercial acrylate or methacrylate monomers that can be used in the polymerization composition disclosed herein include but are not limited to mono-functional (meth)acrylate SR-339, SR-340 and SR-495; di-functional (meth)acrylates SR-230, SR-252, SR-259, SR-268, SR-272, SR-344, SR-603 and SR610; tri-functional acrylates SR-454 and SR-499, all from Sartomer Company.

Any UV or thermal free radical initiator or mixture of initiators known to those skilled in the art of free radical polymerization can be used to initiate polymerization. Mixtures of the photoinitiators are sometimes preferred since they can in certain cases provide a more efficient production of radicals. Concentrations of the initiator in the polymerizable composition typically range from 0.1 to 5% by weight. There are a number of commercially available UV initiators. Examples include but are not limited to Irgacure 184, and Darocur 2959 or 1173 sold by Ciba Specialty Chemical Co.. Other UV and thermal initiators include benzophenone, trimethylbenzophenone, isopropylthioxanthone, and ethyl 4-(dimethylamino)benzoate, benzoyl peroxide, acetyl peroxide, lauryl peroxide, t-butyl peroxide, t-butyl hydroperoxide, bis(isopropyl) peroxydicarbonate, benzoin methyl ether, 2,2′-azobis (2,4-dimethylvaleronitrile), diethoxyacetophenone, 1-hydroxycyclohexyl phenyl ketone and 2,2-dimethoxy-2-phenyl-acetophenone.

Additives such as dispersants, surfactants, antioxidants, light stabilizers and coating aids, that may be included to aide during the dispersing of the spacer particles and impart other desirable properties to the spacer-resin mixture as known to those skilled in the art.

In yet another embodiment of the present invention, the sealant compound is comprising of: (a) UV or thermal curable polyurethane (meth)acrylate oligomers and/or acrylated polyester oligomers, (b)radical polymerizable monomers, (c) an epoxy acrylates, (d) photo-initiators or thermal-initiators and (e) additives.

The (meth)acrylate oligomers, radical-polymerizable monomers, initiators and additives to be used in sealant composition can be the same or different as in the resin composition. The epoxy resin can usually increasing adhesion and improving solvent resistance , thus further strength the sealant desired properties. Examples of suitable commercial epoxy (meth)acrylates can be used in the polymerizable composition disclosed herein included but not limited to epoxy methacrylates CN-104, CN-111, CN-120 and CN-124; epoxy methacrylate CN-151, all from Sartomer Company.

The following examples are provided to further illustrate the present invention. The specific limitations set forth in the following examples are intended as illustrative and not limitative.

### EXAMPLE 1

This example demonstrates the method of dispersing certain amount of spacer on a gravure cylinder with well finished designed pattern holes to be used as the spacer carrier.

A gravure cylinder with honey comb pattern design as shown on the FIG. 8 was used as the spacer carrier. The opening diameter of each hole was around 12 microns and the depth of the hole was about 9 microns.

The monosized polystyrene microsphere dispersion with particle diameter of 7.9 microns purchased from Magsphere Inc. was used as liquid crystal display spacer. A small amount of such spacer dispersion was dispersed on the gravure cylinder as described above. The cylinder was rolling at the direction of pointed arrow as indicated in the FIG. 5, the stationary doctor blade forced only one spacer into each hole on the gravure cylinder and the excess spacers were removed by the function of the doctor blade. The result of spacers resided in the holes of gravure cylinder were shown on the FIG. 9.

### EXAMPLE 2

This example demonstrate the method of transfer spacer from the gravure cylinder onto the smooth surface of roller cylinder as shown in the FIG. 5.

When gravure cylinder carried patterned spacers was pressed on the smooth surface of styrene-isoprene block copolymer rubber plate. The result was shown in FIG. 10.

### EXAMPLE 3

This example demonstrates the method of transfer spacers from rubber cylinder onto the surface of LCD substrate as shown in the FIG. 5.

The glass slide coated with a thin film of PVP K-15 was used to mimic LCD substrate.

By gently press the rubber plate from Example 2 on coated glass slide, patterned spacers were transferred onto the glass slide as shown on the FIG. 11.

This invention has been described with reference to its preferred embodiments. Variations and modifications of the invention described herein will be obvious to those skilled in the art from the foregoing detailed description of the invention. It is intended that all of these variations and modifications be included within the scope of the appended claims.

I claim:

1. A method for placing spacer uniformly and securely onto the substrate of a liquid crystal display element, comprising the steps of:
(a). Preparing an UV [or thermal] curable resin containing spacer particles.
(b) Dispersing certain amount of above spacer-resin mixture on a gravure cylinder with well finished designed cells to be used as the spacer-resin carrier.
(c) Removing excess spacer-resin mixture and forced spacer particle with resin into each hole by means of doctor knife.
(d) Transferring individual spacer-resin onto a second smooth surfaced roller according to the designed pattern by means of contact.
(e) Transferring individual patterned spacer-resin onto the surface of substrate of a liquid crystal display element from the second roller with any conventional coating methods.

2. A spacer-resin composition in part (a) of claim 1 is comprising::
(a) An uniform size of spacer particles, either made of plastic or glass. The shape of spacer particles can be spherical or rod-like.
(b) UV or thermal curable (meth)acrylated oligomers.
(c) Vinyl monomers or (meth)acrylate monomers.
(d) Photo-initiators or thermal-initiators.
(e) Additives.

3. The additives in part (e) of claim 2 can be dispersants, surfactants, antioxidants, light-stabilizers and coating aids which aiding dispersing ability of spacer particles during mixing or impart other desirable properties to the spacer-resin mixture.

4. The gravure roller used in part (b) of claim 1 should made of hydrophobic, non-adhesive layer with thickness greater than twice of the diameter of the spacer particles.

5. The hydrophobic, non-adhesive layer in claim 4 is Teflon.

6. The hydrophobic, non-adhesive layer in claim 4 is a low surface energy fluorinated polymer.

7. The size of the hole in part (b) of claim 1 has an opening diameter and the depth both at 105-195% of the diameter of the spacer particle.

8. The gravure roller used in part (b) of claim 1 can be engraved the metal cylinder first, then coated with a thin layer of hydrophobic, non-adhesive coating.

9. The, hydrophobic, non-adhesive thin layer in claim 8 is Teflon.

10. The hydrophobic, non-adhesive thin layer in claim 8 is a low surface energy fluorinated polymer.

11. A method for placing sealant uniformly and securely onto the substrate of a liquid crystal display-element, comprising the steps of:
(a) Preparing an UV (or thermal) curable sealant containing spacer particles.
(b) Dispersing certain amount of above spacer-sealant mixture on a gravure cylinder with channel-like design pattern to be used as the spacer-sealant carrier.
(c) Removing excess spacer-sealant mixture and forced correct amount of spacer-sealant mixture into the channel.
(d) Transferring a strip of spacer-sealant mixture onto a second smooth surfaced roller according to the designed pattern by means of contact.
(e) Transferring the patterned spacer-sealant strip onto the surface of substrate of a liquid crystal display element from the second roller with any conventional coating methods.

12. An adhesive spacer-sealant composition in part (a) of claim 11 is comprising:
(a) An uniform size of spacer particles, either made of plastic or glass. The shape of spacer particles can be spherical or rod-like.
(b) UV or thermal curable (meth)acrylated oligomers.
(c) Vinyl monomers-or (meth)acrylate monomers.
(d) An epoxy (meth)acrylates.
(e) Photo-initiators or thermal initiators.
(f) Additives.

13. The additives in part (f) of claim 12 can be dispersants, surfactants, antioxidants, light-stabilizers and coating aids which aiding dispersing ability of spacer particles during mixing or impart other desirable properties to the spacer-sealant mixture.

14. The gravure roller used in part (b) of claim 11 should made of hydrophobic, non-adhesive layer with thickness of greater than twice of the diameter of the spacer particles.

15. The hydrophobic, non-adhesive layer in claim 14 is Teflon.

16. The hydrophobic, non-adhesive layer in claim 14 is a low surface energy fluorinated polymer.

17. The depth of the channel in part (b) of claim 11 is about 105-195% of the diameter of the spacer particle.

18. The gravure roller used in part (b) of claim 11 can be engraved the metal cylinder first, then coated with a thin layer of hydrophobic, non-adhesive coating.

19. The hydrophobic, non-adhesive thin layer in claim 18 is Teflon.

20. The hydrophobic, non-adhesive thin layer in claim 18 is a low surface energy fluorinated polymer.

21. A method to bond two coated substrates to form a liquid crystal display device by radiation energies.

22. The radiation energy in claim 21 is ultra-violet radiation energy.

23. The radiation energy in claim 21 is thermal radiation energy.

24. The coated substrate in claim 21 is the substrate coated with spacer-resin as in claim 1.

25. The other coated substrate in claim 21 is the substrate coated with spacer-sealant as in claim 11.
